(19) United States
(12) Patent Application Publication
(10) Pub. No.: US 2004/0237889 A1
(43) Pub. Date: Dec. 2, 2004

(54) Chemical gas deposition process and dry etching process and apparatus of same

(75) Inventors: Wei-Tsong Chen, Hsinchu (TW); Ching-Chung Yang, Hsinchu (TW); Chung-Chieh Juan, Hsinchu (TW)

Correspondence Address: BACON & THOMAS, PLLC, 625 SLATERS LANE, FOURTH FLOOR, ALEXANDRIA, VA, 22314

(73) Assignee: Winbond Electronics Corporation, Hsinchu (TW)

(21) Appl. No.: 10/446,182

(22) Filed: May 28, 2003

(51) Int. Cl. C23C 16/00

(52) U.S. Cl. 118/715

(57) ABSTRACT

An improved chemical gas deposition process includes delivering materials to be deposited through a heating pipe for heating then conveying the materials to a gas dispensing head. The temperature of the gas dispensing head is controlled to maintain the ejecting deposition materials in a stable temperature condition. The invention also provides an improved apparatus for the chemical gas deposition process that includes a heat exchanger to control the temperature of the gas dispensing head. By means of the process and apparatus of the invention, the process of chemical gas deposition or dry etching is more stable and efficient.

### BACKGROUND OF THE INVENTION

1. Field of the Invention

The invention relates to an improved chemical gas deposition process and dry etching process and apparatus of same.

2. Description of the Prior Art

In the semiconductor and chemical fields, chemical gas deposition is one of the approaches that is frequently used to grow thin films. The materials required to grow the thin films generally include gas materials and liquid materials. In recent years, in order to reduce granules caused by nuclear uniform problem, the gas materials are often being replaced by the liquid materials. For instance, tetraethyl orthosilicate (TEOS) has replaced SiH₄; or Triethyl Borate (TEB), Trimethyl Phosphate (TMOP), Trimethyl Borate (TMB) that are less toxic have replaced PH₃, B₂H₆, etc.

When used the liquid materials mentioned above for chemical gas deposition, the general approach is to transform the liquid materials to gases through various methods. The materials usually exist in the condition of constant saturated vapor pressure. As the saturated vapor pressure of the same material varies at different temperatures, when the material is transformed to gas, and before being delivered to a gas dispensing head of the chemical gas deposition apparatus for reaction, a temperature control is applied to stabilize the gas temperature at a desired level. Otherwise the concentration of the gas changes due to temperature variations during the material is transformed from liquid to gas, and the manufacturing process could become unstable. This could result in quality problem during growing the thin films. On the other hand, the gas material may be cooled and condensed in liquid and result in gas line pollution.

Because of the importance of temperature control to the chemical gas deposition process, the chemical gas deposition processes now being adopted in the industry generally use a heat tape to wrap and cover the gas line to control the temperature of the gas delivery system. Refer to FIG. 1 for a conventional chemical gas deposition process in which only the gas line is wrapped by the heat tape for controlling the temperature in the line. However, there is no temperature control at the end of the gas delivery (i.e. the gas dispensing head). As a result, control of gas concentration loses before the gas has been delivered to the gas dispensing head and accuracy of controlling gas concentration cannot be achieved.

The gas of the deposition material which is delivered to the gas dispensing head does not have reaction yet. Hence temperature variations at that spot has impact on the growing quality of the thin films. Too much temperature variations will result in suffering of process efficiency. Therefore it is necessary to have more precise temperature control for the elements in the process.

In addition, in the practical production process, equipment have to be repaired and maintained frequently. External interference on the equipment often causes temperature control of the gas dispensing head difficult, and restoring to normal process conditions could take a long time.

### SUMMARY OF THE INVENTION

In view of the aforesaid disadvantages, the primary object of the invention is to provide an improved chemical gas deposition process to overcome the problems mentioned above.

Another object of the invention is to provide an apparatus adopted for use in the improved chemical gas deposition process.

A further object of the invention is to provide an improved dry etching process.

Yet another object of the invention is to provide an apparatus adopted for use in the improved dry etching process.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a schematic diagram of a conventional chemical gas deposition apparatus.

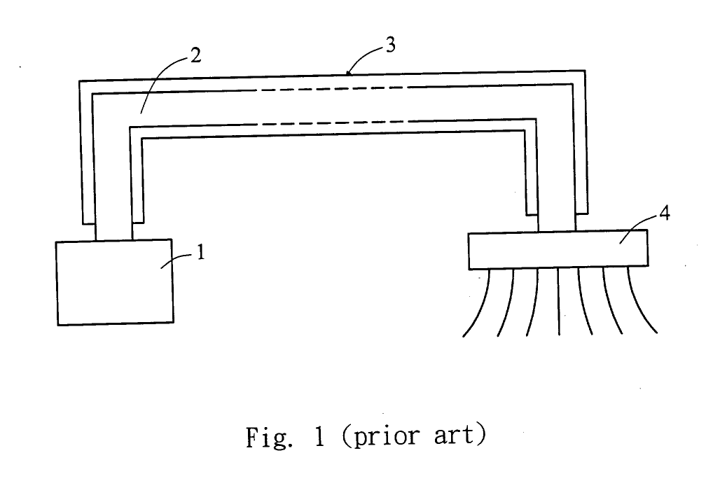

FIG.2 is a schematic diagram of a chemical gas deposition apparatus (or an improved dry etching process) of the invention.

### DESCRIPTION OF THE PREFERRED EMBODIMENTS

The improved chemical gas deposition process of the invention includes conveying materials to be deposited through a heating pipe for heating then delivering the materials to a gas dispensing head. The temperature of the gas dispensing head is controlled so that the deposition materials being ejected are controlled at a stable temperature.

The invention further provides an improved dry etching process which includes conveying materials for etching through a heating pipe for heating then delivering the materials to a gas dispensing head. The temperature of the gas dispensing head is controlled so that the etching materials being ejected are controlled at a stable temperature.

In the improved chemical gas deposition process and the improved dry etching process of the invention, the processes of conveying materials through the heating pipe and delivering to the gas dispensing head are known in the art, thus details are omitted. However, the heating temperature of the heating pipe varies according to material properties of the deposition. In general, it is the temperature of the liquid material at the constant saturated vapor pressure.

The improved chemical gas deposition process and the improved dry etching process of the invention mainly control the temperature at the gas dispensing head to enable the materials passing through the gas dispensing head be ejected at a stable temperature.

There is no restriction for the temperature control methods. Any technique that is capable of controlling the temperature of the gas dispensing head may be adopted. For instance, a general heat exchanger may be employed. To be more specific, a metal conductive pipe may be coupled with the dispensing head to serve as a temperature control contact unit. The temperature control contact unit may be connected to a heat transmission line which in turn is connected to a heat exchanger. The temperature control contact unit, heat transmission line and heat exchanger have cooling/heating media flow through to perform heat exchange. The thermal energy transmitted from the gas dispensing head is cooled in the heat exchange by means of an external cooling unit and is heated by means of a heating unit in the heat exchanger. When the temperature of the gas dispensing head is too high, the cooling unit performs cooling function. When the temperature of the gas dispensing head is too low, the heating unit in the heat exchanger performs heating so that the temperature of the gas dispensing head may be controlled at a stable condition.

The temperature of the gas dispensing head mates the temperature of the heating pipe and may be selected depending on the material to be deposited, and adjusted in an optimal manner according to different process environments. In general, the temperature employed is the temperature which the liquid material reaches the saturated vapor pressure.

The invention further provides an improved apparatus for chemical gas deposition process. Its main feature is to use a heat exchanger coupled with the gas dispensing head to control the temperature of the gas.

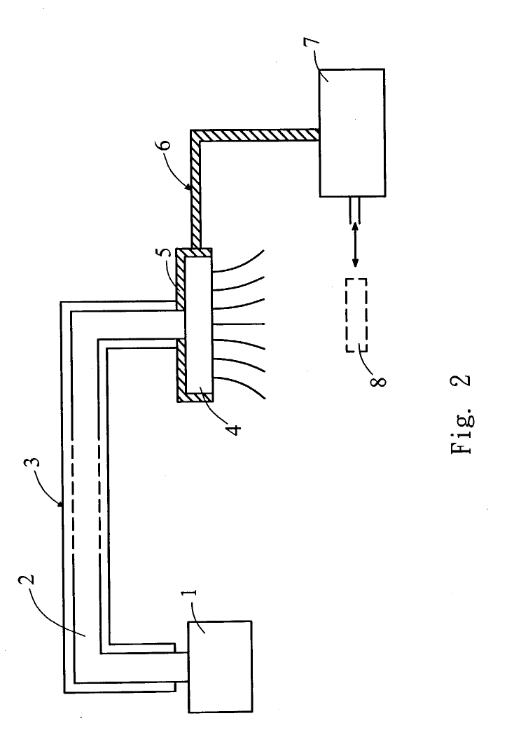

Refer to FIG. 2 for the improved apparatus of chemical gas deposition process of the invention. It includes a material tank 1 for holding materials to be deposited, a gas line 2 connecting to the material tank 1. The gas line 2 is covered by a heating pipe 3 to control the temperature of the materials to be deposited. The gas line 2 has another end connecting to a gas dispensing head 4. The gas dispensing head 4 is coupled with a temperature control contact unit 5 from outside. The temperature control contact unit 5 connects to a heat transmission line 6 which has another end connecting to a heat exchanger 7. The heat exchanger 7 has a heating unit and connects to an external cooling apparatus 8 for providing heating and cooling functions simultaneously.

The invention also provides an improved apparatus for dry etching process. Its main feature is to use a heat exchanger coupled with the gas dispensing head to control the temperature of the gas.

Refer to FIG. 2 for the improved apparatus of dry etching process of the invention. It includes a material tank 1 for holding etching materials, a gas line 2 connecting to the material tank 1. The gas line 2 is covered by a heating pipe 3 to control the temperature of the etching materials. The gas line 2 has another end connecting to a gas dispensing head 4. The gas dispensing head 4 is coupled with a temperature control contact unit 5 from outside. The temperature control contact unit 5 connects to a heat transmission line 6 which has another end connecting to a heat exchanger 7. The heat exchanger 7 has a heating unit and connects to an external cooling apparatus 8 for providing heating and cooling functions simultaneously.

According to the apparatus of the invention, the gas dispensing head is coupled with the temperature control contact unit. Hence when other adjoining process elements make the gas dispensing head overheated, the temperature control system provides cooling function to prevent the gas dispensing head from being overheated or affecting the stability of the gas. When the gas dispensing head is affected by external environments and results in a lower temperature, the temperature control system can provide heating through the heating unit of the heat exchanger to maintain a stable temperature for the gas dispensing head and to prevent product quality from being affected by the unstable process conditions.

I claim:

1. A chemical gas deposition process comprising:
delivering materials to be deposited through a heating pipe for heating;
conveying the materials to a gas dispensing head; and
controlling the temperature of the gas dispensing head to stabilize the temperature of the ejecting deposition materials.

2. The chemical gas deposition process of claim 1, wherein the temperature of the heating pipe is the temperature for maintaining the materials to be deposited at the constant saturated vapor pressure.

3. The chemical gas deposition process of claim 1, wherein the temperature of the gas dispensing head is controlled for maintaining the materials to be deposited at the constant saturated vapor pressure.

4. An apparatus for a chemical gas deposition process, comprising:
a material tank for holding materials to be deposited;
a gas line connecting to the material tank;
a heating pipe covering the gas line to control the temperature of the materials to be deposited;
a gas dispensing head connecting to another end of the gas line;
a temperature control contact unit coupling with the exterior of the gas dispensing head;
a heat transmission line connecting to the temperature control contact unit;
a heat exchanger connecting to another end of the heat transmission line and including a heating unit; and
a cooling apparatus externally connecting to the heat exchanger thereby to provide heating and cooling functions simultaneously.

5. The apparatus for a chemical gas deposition process of claim 4, wherein the temperature control contact unit, the heat transmission line and the heat exchanger have cooling/heating media flowing through and processing heat exchange through a flowing fluid fashion.

6. The apparatus for a chemical gas deposition process of claim 4, wherein cooling apparatus cools the temperature of the gas dispensing head when the gas dispensing head is overheated.

7. The apparatus for a chemical gas deposition process of claim 4, wherein the heating unit of the heat exchanger heats the gas dispensing head when the temperature of the gas dispensing head is below a selected level.

8. The apparatus for a chemical gas deposition process of claim 4, wherein the gas dispensing head has a built-in electric heater and a cooling water circulation system.

9. The apparatus for a chemical gas deposition process of claim 4, wherein the gas dispensing head is covered by a heat tape.

10. A dry etching process comprising:
delivering etching materials through a heating pipe for heating;
conveying the materials to a gas dispensing head; and
controlling the temperature of the gas dispensing head to stabilize the temperature of the ejecting etching materials.

11. The dry etching process of claim 10, wherein the temperature of the heating pipe is the temperature for maintaining the etching materials at the constant saturated vapor pressure.

12. The dry etching process of claim 10, wherein the temperature of the gas dispensing head is controlled for maintaining the etching materials at the constant saturated vapor pressure.

13. An apparatus for a dry etching process, comprising:
a material tank for holding etching materials;
a gas line connecting to the material tank;
a heating pipe covering the gas line to control the temperature of the etching materials;
a gas dispensing head connecting to another end of the gas line;
a temperature control contact unit coupling with the exterior of the gas dispensing head;
a heat transmission line connecting to the temperature control contact unit;
a heat exchanger connecting to another end of the heat transmission line and including a heating unit; and
a cooling apparatus externally connecting to the heat exchanger thereby to provide heating and cooling functions simultaneously.

14. The apparatus for a dry etching process of claim 13, wherein the temperature control contact unit, the heat transmission line and the heat exchanger have cooling/heating media flowing through and processing heat exchange through a flowing fluid fashion.

15. The apparatus for a dry etching process of claim 13, wherein cooling apparatus cools the temperature of the gas dispensing head when the gas dispensing head is overheated.

16. The apparatus for a dry etching process of claim 13, wherein the heating unit of the heat exchanger heats the gas dispensing head when the temperature of the gas dispensing head is below a selected level.

17. The apparatus for a dry etching process of claim 13, wherein the gas dispensing head has a built-in electric heater and a cooling water circulation system.

18. The apparatus for a dry etching process of claim 13, wherein the gas dispensing head is covered by a heat tape.
